(19) United States
(12) Patent Application Publication
(10) Pub. No.: US 2002/0054513 A1
(43) Pub. Date: May 9, 2002

(54) Method for program revise of an IC smartcard system

(76) Inventor: Yan-Shun Kao, Taipei (TW)

Correspondence Address: POWELL, GOLDSTEIN, FRAZER & MURPHY LLP, P.O. BOX 97223, WASHINGTON, DC, 20090-7223, US

(21) Appl. No.: 09/950,421

(22) Filed: Sep. 12, 2001

(30) Foreign Application Priority Data
Sep. 14, 2000 (TW) 89118872

(51) Int. Cl. G11C 7/00; G11C 5/00

(52) U.S. Cl. 365/189.01; 365/230.03; 365/221

(57) ABSTRACT

A method for modifying program in EEPROM of an IC smart card system. First, save the operating program of IC smart card system in a ROM, the operating program has a function of Add Command. Next, increase the content of the command code before formatting the IC smart card, wherein the increased command code and the actual content are saved in an EEPROM. Then, formatting the IC smart card to define the file segment of the EEPROM, and finally input personal data in the IC card to complete the card activating procedure. By using the program modification method, the time for the IC card producing is reduced and the efficiency is improved when there are small changes of the functions of the IC card.

### FIELD OF THE INVENTION

This present invention relates to an Integrated Circuit smartCard (ICC) system program, especially about a method used for modifying a program in an Electrically Erasable and Programmable ROM (EEPROM) of an IC smart card system.

### BACKGROUND OF THE INVENTION

When modern technology improves, life style of people also varies, and the plastic money (for example, the credit card) becomes the most important paraphernalia with people. However, because the uses of credit card are more diverse and extensive, secrets keeping and security also become the hidden issues of the business transaction. Additionally, there is one kind of card called Integrated Circuit Card (ICC) with an IC chip attached and act like a super mini-computer with data saving and calculating function. It not only includes the traditional functions like withdrawing money from ATMs, dialing on pay telephones, and shopping, but also combines with contract stores or medical system; it provides the functions of identifying identity, recording medical anamnesis, and electric wallet etc., and also provides more secrets keeping and security ability.

Referring to FIG. 1, it is a standard appearance view of an IC smart card. The IC smart card 100 has a convex area 130 and a chip 120 on its obverse side. The convex area 130 has traditional identification number for reading or marking by machines (for example, a credit card could transfer the number to an invoice by simple tools when shopping), and its position and type are all ruled in ISO 7811. There are usually several electric contact points on the chip 120, including essential points (for example, the black contact points in the figure) for Vcc, RST, CLK, GND and transfer of I/O signals, and points which are not used (for example, the white contact points in the figure). Besides, no. 110 is the magnetic belt on the reverse side of the card, and it usually has three tracks for a Pick-up head to read information.

We could develop various application programs to satisfy customers' needs conveniently with an IC smart card which is provided with a microprocessor chip, so the uses of an IC smart Card are very diverse, and the space problem of data saving is the only limitation. But as a result of the rapid development of the semi-conductor industry in recent years, the line width of integrated circuits is much thinner (under 0.18-μm), the degrees of integration are much higher, and the development of an IC smart card is expectable.

When producing an IC smart card which contains a chip traditionally, we could use the software simulator of chips to write programs and check them in order to improve the procedures of software researching and developing and the hardware emulator for actual examination. Without any error in examination, we edit the application program of a card to become an executable file and bum it into a Mask ROM as firmware. This software includes the OS of a chip and the application program which customers need. However, because the program has been burned in ROM, if users dissatisfy the functions of a card, we will modify the program and reproduce the IC chip with modified program to fit customers' needs. If the range which requires to modify is large and it is probably limited by the space problem of an IC smart card, redeveloping one new card is a necessary way. If customers only dissatisfy some parts of the functions, it is not efficient to redevelop another card, because it spends much money and time in reproducing a card (about 3˜6 months). Therefore it needs one new way very much to solve the problems as described above.

### SUMMARY OF THE INVENTION

In the background of the invention as described above, a traditional Integrated Circuit Card (ICC) program is burned into ROM. When customers have different needs, we must reproduce one new card, and it costs very much and is not efficient. One of the major purposes of the present invention is to fit different needs by using the function of operating program installed in an IC smart card chip to save the modified program in EEPROM.

The more particular purpose of the invention is to satisfy different customers' needs by modifying partial program of the chip in an IC smart card without reproducing cards.

According to the purposes described above, this present invention will be simply described:

In the first step, develop a chip by semi-conductor process on a silicon wafer, and burn an executable file into ROM. After completing and testing the chip, cut the chip and connect it with the external pins. Then, combine the chip with a card made by polyvinyl chloride or the like materials, and follow the normal card-activating procedure. If customers need another function in which the program in the card does not have, we will use the Add Command function designed in the operating program to modify the program. Now the new command and content are saved in the application program data segment of EEPROM to replace the unsuitable code of the original program, and the content of the command will be saved in the suitable address by the WRITE₁₃ BINARY order in binary system.

After saving the modified code in EEPROM, the next procedure is pre-personalization of a chip in order to transfer some program and data file to the chip. Then, perform the personalization of personal data, and personal names, passwords and account numbers etc are saved into the file segment in EEPROM in this procedure.

When using the IC smart card actually, the operation system will search the relating command in EEPROM, and when finding the command, it will execute the modified function, or it will return to search the command in ROM to execute the installed function. By modifying the program in the invention, we can not only use the resources in the IC smart card effectively, but also save the cost of producing another cards and improve the efficiency of card activating.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is an appearance figure of an IC smart card;

FIG. 2 is a hardware construction diagram of a chip in an IC smart card;

FIG. 3 is a flow chart of producing an IC smart card according to this invention;

FIG. 4 is a diagram of relations between ROM and EEPROM according to the IC smart card in the present invention;

FIG. 5 is an arrangement diagram of EEPROM in the IC smart card in the present invention;

FIG. 6 is a flow chart of users who operate a modified card according to the IC smart card in the present invention; and

FIG. 7 is a structure diagram of adding new commands in EEPROM of an IC smart card according to one embodiment of the present invention.

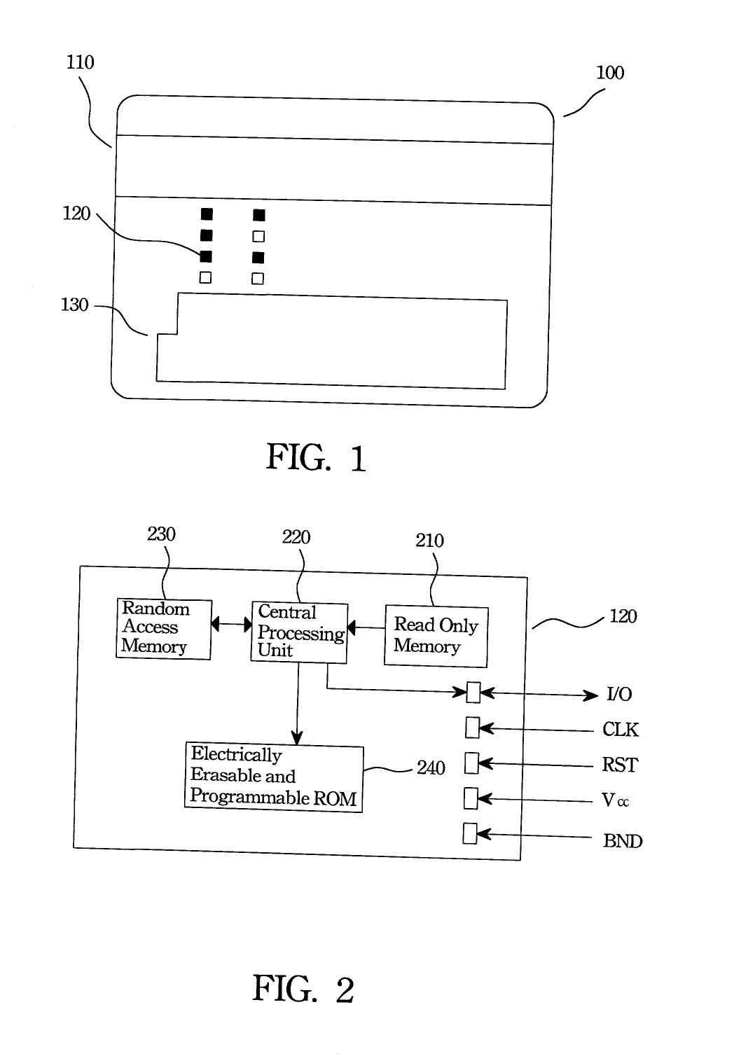

### DETAILED DESCRIPTION OF THE PREFERRED EMBODIMENT

This invention discloses a method for modifying the program by EEPROM of an Integrated Circuit Card (ICC). The detailed description of this invention will be as follow:

Referring to FIG. 2, this is a hardware arrangement diagram of a chip in an IC smart card. The IC smart card 120 comprises Read Only Memory (ROM) 210 with operation system, Random Access Memory (RAM) 230, Electrically Erasable and Programmable ROM (EEPROM) 240 and Central Processing Unit (CPU) 220. A program is only saved in ROM by masking process when producing a chip, after that it just can be read and cannot be modified. Saving the operation system and executable code of the program in ROM 210 can also improve the security of a chip. Besides, Ram 230 is a volatile memory whose content will be lost as the power is off, and it can be the buffer memory of variables, registers, stacking, password calculating formula and Input/Output when the program is executed. As a result of the finite space of RAM in an ordinary IC smart card, a program designer has to control the usable memory space carefully.

The EEPROM 240 is a nonvolatile memory whose content will not be lost as the power is off. When erasing and re-inputting data, it can be done in one bit and one bit, and is also suitable for program or data saving in an IC smart card. But the slow writing and reading speed and the restricted number of times are its defects. Except for EEPROM, we can also use flash memory or others for replacing. At last, the core processor of a general IC smart card is a 8 bit microprocessor (for example, Motorola 6805 or Intel 8051 etc.) and this kind of CPU can only deal with one byte of data at a time, but its instruction for dealing of memory and register, addressing mode and input/output operation still has certain ability, and it is also sufficient for an IC smart card therefore. Furthermore, in FIG. 2, the external connecting points of the chip are the I/O interface, CLK, RST, Vcc and GND of serial transfer.

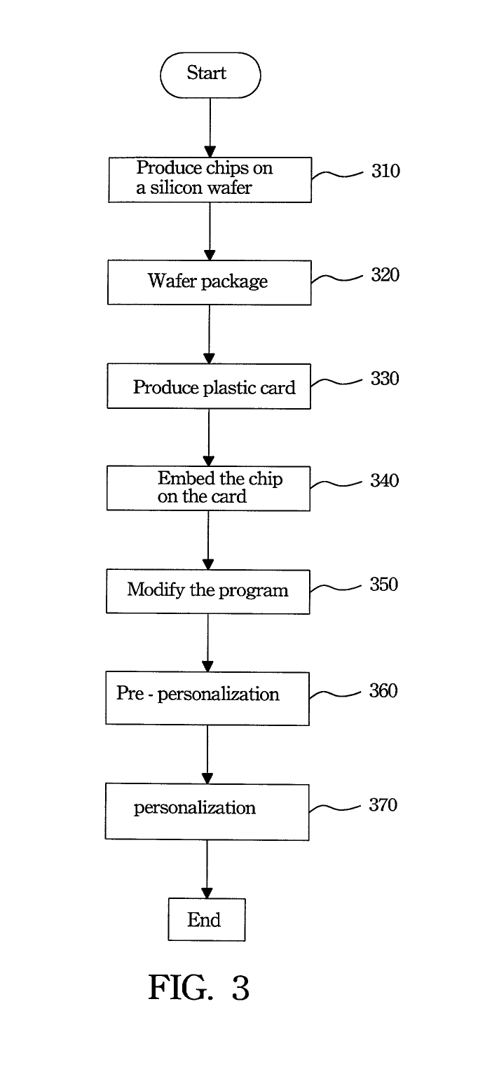

With regard to the flow chart of modifying a program in the invention, please refer to the producing and activating flow chart of an IC smart card in FIG. 3. First, produce thousands of transistor chips on a single crystalline grain by semiconductor processes on a silicon wafer (step 310). These kinds of semiconductor processes usually need to develop a new mask, and the mask also includes an IC smart card program which has been developed and tested before production in order to be saved in ROM. This step is usually called a masking step. In the next step, when the chip is completed, every grain on the silicon wafer needs to examine its function practically, then cut the grain and proceed with wafer package (step 320). At the same time of producing a chip, it also can produce a card (step 330) by using polyvinyl chloride or the like. After completing the chip and card, we can embed the chip in the card (step 340). Afterwards, the IC smart card is sent to the system merchant to continue the following card activating procedure.

We usually divide the IC smart card software into two kinds of software; one is executed on the computer and the other is executed on the IC smart card. As a result of the improvement of computer hardware, general high-level computer languages like C++, Java and Basic can all be used to write software applied in a client computer of an IC smart card, and low-level language like assembly language can be used to write software in the card. Then, the two kinds of software can be connected by Interface Device (IFD) in serial transfer means through the I/O interface described above.

In the invention, an IC smart card which have been produced has saved an operating system and an application software in ROM, and it can be delivered to customers only after normal card activating and message writing procedure (for example, personal data.) But if customers have different needs, it needs to follow the program modifying procedure in step 350. Because the program in ROM cannot be modified, it needs to use EEPROM to save the modified program. This invention replaces the unsuitable content of the original program by a function of Add Command in the original program and saves the new command and content in EEPROM. It will be more specifically described in detail with the method and the corresponding embodiments as below.

After the program modification in step 350, the next is the pre-personalization procedure of step 360. In order to complete the function of a card that the specific customer needs, we must transfer some programs or data to a chip first. This step is, for example, to initialize a chip by a reset signal sent by a computer. Then proceed the formatting and the logic test of EEPROM by testing the state variables (make sure that the program is entering the initializing step) and save the required data to the designed address. Finally, the card activating procedure is personalization of personal data in step 370, at this time to save the data like personal data (name), accounts of bank and personal identification number (PIN) to a stationary address, and the user who owns this IC smart card can ascertain his right to use by the personal data.

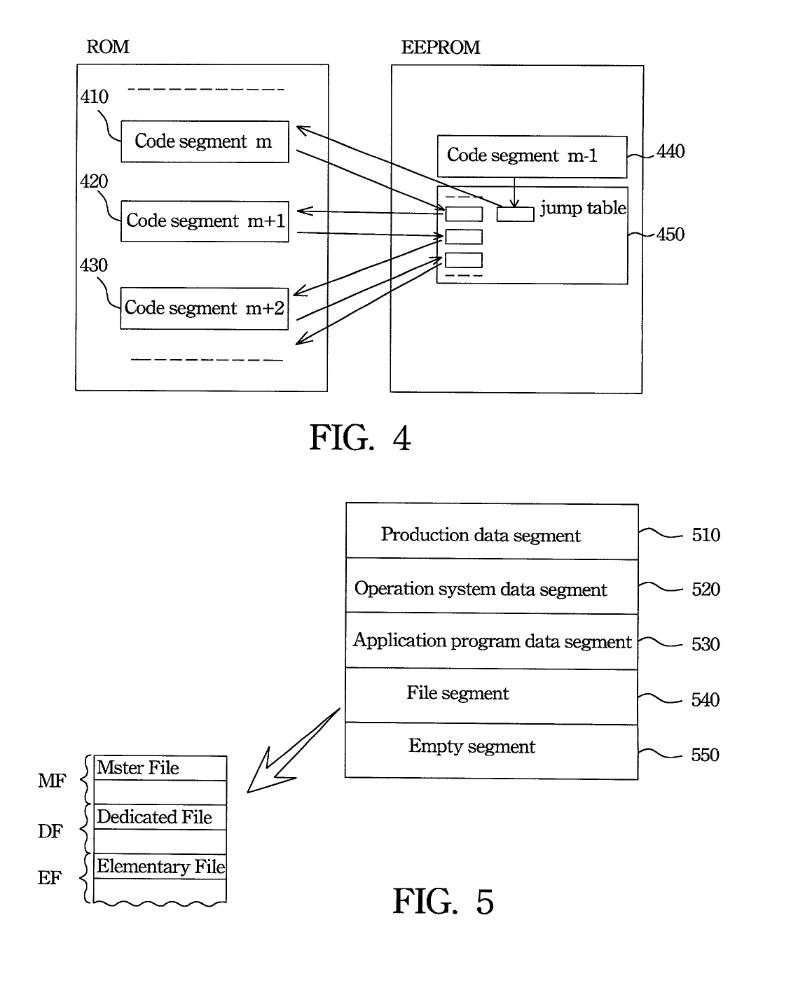

Referring to FIG. 4, this FIGURE reveals the relation between the code segment in ROM and EEPROM. It is worth noticing that at the stage which chips are just be produced, although ROM has an operating system of IC smart card system, the EEPROM is actually empty. Consequently, all the code segments should only be executed in ROM. But after completing partial modification of the program according to this invention, some parts of code segment m-1 (440) are installed in EEPROM. When the program is executed, it probably chooses the segment m-1 (440) in EEPROM according to the jump table 450, and then chooses the next code segment m (410), code segment m+1 (420) and code segment m+2 (430). The code segment m-1 (440) is saved the content of the program modified by the method of this present invention.

Referring to FIG. 5, this figure reveals the structure of EEPROM according to this present invention. The structure and price of EEPROM are usually much more expensive than RAM and ROM, and in order to use this memory properly, we usually divide EEPROM into several different segments. For example: (1) production data segment 510. The data in the segment is singular and written in only once, and it is usually put in the beginning area of EEPROM; (2) operation system data segment 520. The segment is saved with the pointer data like system and table, for example, the jump table in FIG. 4, and at the same time, it can become a complete IC smart card system by combining the data in this segment and the program in ROM. In addition, in order to ensure the safety and stability of IC smart card system, the segment is usually protected in the checksum means; (3) application program data segment 530. The segment is the modified code segment in this present invention; (4) file segment 540. The structure of the file segment will be separated into Master File (MF), Dedicated File (DF) below MF, and Elementary File (EF) below DF like the tree structure in a computer, and the personal data of IC smart card described above can be saved in EF; (5) empty segment 550. This segment can be used for the extension of file segment or other application area.

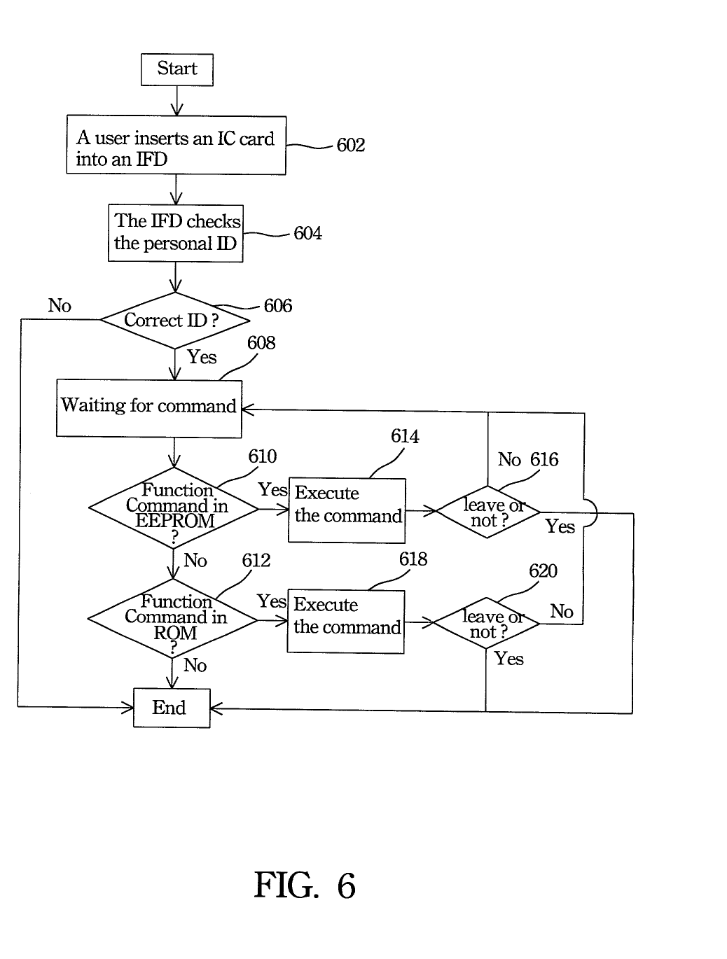

Referring to FIG. 6, this is an operating flow chart of IC smart card with a modified program according to the present invention. When a user inserts an IC card into an IFD (step 602), the IFD will check the personal ID of the user (step 604). After identifying the correctness by the computer connected to the IFD, if the ID is not correct, it means that the user is not authorized, and the procedure will be closed; if the ID is correct, the system will entered into the stage of waiting for command (step 608). Afterwards, when the function command input by the user is in EEPROM (step 610), the computer will execute the command (step 614), and determine to leave this procedure or wait for the next command (step 616). When the command that the user input is not in EEPROM, the computer will check and see if the command is in ROM or not. If it is an illegal command, the procedure will be closed, or the command will be executed and the computer will determine to leave this procedure or wait for the next command (step 620).

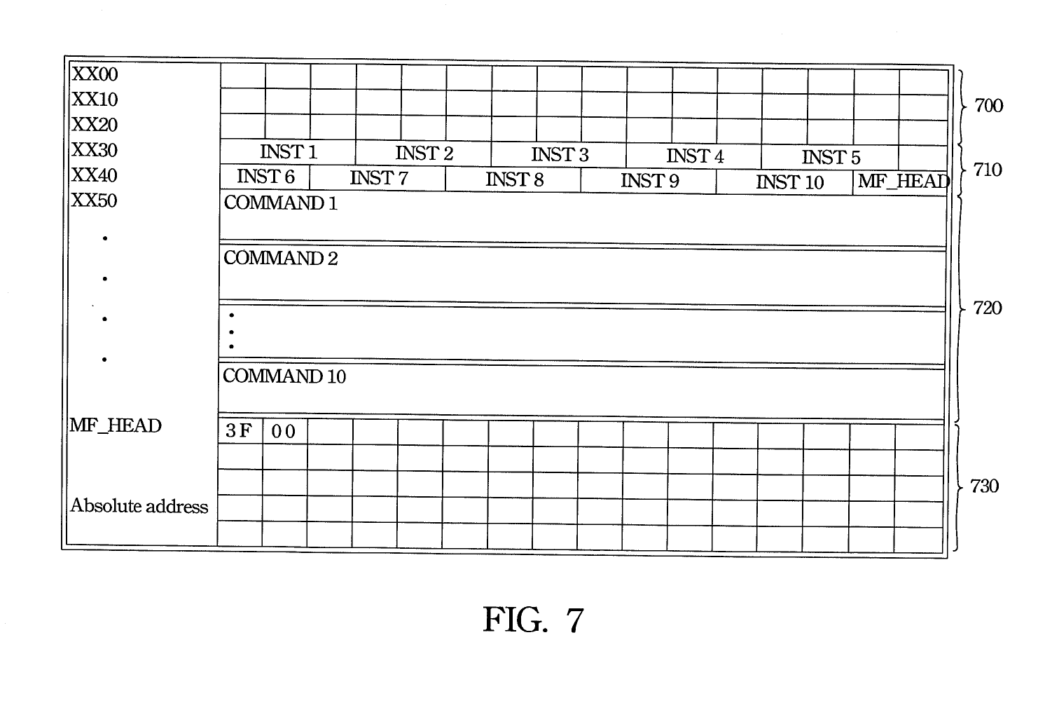

Referring to FIG. 7, this is a structure diagram of an embodiment of EEPROM with a modified program according to this present invention. The EEPROM here is divided into four segments:

(1) segment 700 with reserved 48 bytes. This segment is equivalent to the production data segment 510.

(2) segment 710 and segment 720 with saved command code and content. The segments belong to the operating system data segment 520 described above, and each command code INSTi(i=1˜10) occupies 3 bytes. The category of command code only occupies one byte, and another 2 bytes represent the address (absolute address) of the command code. It means:

INSTi=code i+address i(i=1˜10)

For example, the content of INST 1 in the address XX30 is pointed to the COMMAND 1 in XX50 in the diagram. That is:

INST 1=code 1+XX50

In this embodiment, it will assign 10 command codes to the modified program and the next MF_HEAD of file segment in the end of command code INSTi, and it also occupies 2 bytes here.

(3) segment 730 with saved file content. This segment saves personal relating data.

In the embodiment, because the system program defines a function of ADD_COMMAND, we can add new program code as the following program at the same time:

VERIFY_TSC
ADD_COMMAND (ADDRESS, INSTi)
...
ADD_COMMAND (ADDRESS, INSTn)
WRITE_BINARY (ADDRESS, CODE)
...
WRITE_BINARY (ADDRESS, CODE)
CLASS | INSTi |

The beginning of the program code is a password identification step. In the next, the command code and its address are written in EEPROM by ADD_COMMAND, and the program of the command is written in proper address by WRITE_BINARY. The format of ADD_COMMAND is, for example,

|CLA|INS|P1|P2|Lc|DATA|

|00|F0|Address|01|Inst|

CLA is a category of command, occupying one byte;

INS is a specific command, occupying one byte;

P1, P2 are addresses parameters, and each occupies one byte;

Lc is the length of the assigned data, and it has to be one;

DATA is the extended alphabetic string, occupying one byte, too.

By the means of modifying programs described above, it does not affect the operation of IC smart card, and the functions of the program are more diverse. When customers have different needs, we can produce one new card for them in a very short time and do not spend much time in re-producing. It saves the cost and is more efficiency.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method of modifying an operating program of an Integrated Circuit Card (ICC), comprising:
saving the operating program of the Integrated Circuit Card in a ROM, wherein the operating program can add a command code;
adding the command code before pre-personalization of the IC card, wherein the command code and the content being saved in a non-volatile memory of the IC card;
formatting the IC card in order to define a file segment of the non-volatile memory; and
proceeding a personalization of the IC card.

2. The method according to claim 1, wherein said non-volatile memory is selected from the group consisted of an Electrically Erasable and Programmable ROM (EEPROM) and a flash memory.

3. The method according to claim 1, wherein said step of adding the command code further comprises using a WRITE_BINARY command to write the content in a binary format into said non-volatile memory.

4. The method according to claim 1, wherein said IC card further comprises a random access memory (RAM) for a temporary data stored area.

5. The method according to claim 1, wherein said IC card further comprises a central processing unit (CPU) for an input/output operation, management of memories and registers.

6. The method according to claim 1, wherein said IC card uses an input/output interface pin for a serial data transmission.

7. The method according to claim 1, wherein said non-volatile memory further divides into a master file segment, a dedicated file segment, and an elementary file segment.

8. The method according to claim 7, wherein the personalization data stored in said elementary file segment.

9. The method according to claim 1, further comprises finding the command code in said non-volatile memory first, then finding the command code in a ROM during an operation of said IC card.

10. A method of modifying an operating program of an Integrated Circuit Card (ICC), comprising:
saving the operating program of the Integrated Circuit Card in ROM, wherein the operating program can add a command code;
adding the command code by using a computer which being connected to an Interface Device (IFD) of the IC card, the command code and content being saved in the Electrically Erasable and Programmable ROM (EEPROM) of the IC card;
formatting the IC card in order to define a file segment of the EEPROM, wherein the file segment is located behind the command code and the content; and
proceeding the personalization of the IC card.

11. The method according to claim 10, wherein said step of adding the command code further comprises using a WRITE_BINARY command to write the content in a binary format into said non-volatile memory.

12. The method according to claim 10, wherein said IC card further comprises a random access memory (RAM) for a temporary data stored area.

13. The method according to claim 10, wherein said IC card further comprises a central processing unit (CPU) for an input/output operation, management of memories and registers.

14. The method according to claim 10, wherein said IC card uses an input/output interface pin for a serial data transmission.

15. The method according to claim 10, wherein said EEPRPOM further divides into a master file segment, a dedicated file segment, and an elementary file segment.

16. The method according to claim 15, wherein the personalization data stored in said elementary file segment.

17. The method according to claim 10, further comprises finding the command code in said EEPROM first, then finding the command code in a ROM during an operation of said IC card.
